(19) United States
(12) Patent Application Publication
(10) Pub. No.: US 2013/0256603 A1
(43) Pub. Date: Oct. 3, 2013

(54) LIQUID COMPOSITION FOR DEPOSITION OF ORGANIC ELECTROACTIVE MATERIALS

(71) Applicants: Reid John Chesterfield, Wilmington, DE (US); Charles D. Lang, Goleta, CA (US); Henry J. Sarria, Isla Vista, CA (US); Hjalti Skulason, Buellton, CA (US)

(72) Inventors: Reid John Chesterfield, Wilmington, DE (US); Charles D. Lang, Goleta, CA (US); Henry J. Sarria, Isla Vista, CA (US); Hjalti Skulason, Buellton, CA (US)

(73) Assignee: E I DU PONT DE NEMOURS AND COMPANY DUPONT DISPLAYS INC, Wilmington, DE (US)

(21) Appl. No.: 13/992,250

(22) PCT Filed: Dec. 20, 2011
(86) PCT No.: PCT/US11/66316

§ 371 Date: Jun. 7, 2013

Related U.S. Application Data
(60) Provisional application No. 61/425,381, filed on Dec. 21, 2010.

(51) Int. Cl. H01L 51/00

(52) U.S. Cl. CPC H01L 51/0034
USPC 252/500

(57) ABSTRACT

Compositions are provided for improved liquid deposition of electroactive material onto low surface energy layers. The liquid composition includes at least one organic electroactive material in a liquid medium. The liquid medium includes (a) at least 20% by volume, based on the total volume of the liquid medium, of a first solvent and (b) at least 1% by volume, based on the total volume of the liquid medium, of a liquid organic additive. The liquid medium pins on the underlying layer as determined by a dynamic receding contact angle test. The first solvent retracts on the underlying layer as determined by the dynamic receding contact angle test.

### RELATED APPLICATION DATA

This application claims priority under 35 U.S.C. §119(e) from U.S. Provisional Application No. 61/425,381, filed on Jun. 17, 2010, which is incorporated by reference herein in its entirety.

### FIELD OF THE INVENTION

The invention relates generally to liquid compositions for the deposition of organic electroactive materials. In particular, the compositions are useful in the deposition of organic materials onto low surface energy surfaces.

### BACKGROUND INFORMATION

Organic electronic devices play an important role in industry. For example, organic light emitting diodes (OLEDs) are promising for display applications due to their high power conversion efficiency and low processing costs. Such displays are especially promising for battery-powered, portable electronic devices, including cell-phones, personal digital assistants, handheld personal computers, and DVD players. These applications call for displays with high information content, full color, and fast video rate response time in addition to low power consumption. OLED's typically contain electroactive layers arranged between an anode and a cathode. Each electroactive layer contributes to the overall performance of the display. Thus, when manufacturing a display containing an OLED, each electroactive layer is carefully deposited in a controlled fashion onto a suitable underlying surface.

One cost-efficient method for depositing electroactive layers in the manufacture of such displays is solution deposition. Solution deposition typically involves depositing a layer from solution using a variety of well-known techniques, such as, e.g., slot die or spin coating, ink-jet and nozzle printing, etc. During the manufacture of the organic electronic device, the formation of the organic material layers using solution processing techniques to create the device can create challenges. As such, one area currently drawing the attention of researchers is the identification of solvents for optimum solution deposition properties, which in turn results in cost-efficient production of devices containing OLED displays.

### SUMMARY

There is provided a liquid composition for liquid deposition onto an underlying layer, wherein the liquid composition comprises at least one organic electroactive material and at least one liquid medium, wherein the liquid medium comprises (a) at least 20% by volume, based on the total volume of the liquid medium, of a first solvent and (b) at least 1% by volume, based on the total volume of the liquid medium, of a liquid organic additive, and wherein the liquid medium pins on the underlying layer as determined by a dynamic receding contact angle test and the first solvent in neat form retracts on the underlying layer as determined by the test.

There is provided a liquid composition for liquid deposition onto an underlying layer, wherein the liquid composition comprises at least one organic electroactive material and a liquid medium, wherein the liquid medium comprises (a) at least 20% by volume, based on the total volume of the liquid medium, of a first solvent and (b) at least 1% by volume of a liquid organic additive, and wherein the liquid additive in neat form is capable of damaging the underlying layer.

There is also provided any of the above liquid compositions which further comprise (c) 5-70% by volume of a second solvent which has a lower surface tension than the first solvent.

There is also provided any of the above liquid compositions which further comprise (d) 0.5-10% by volume of a third solvent has a lower vapor pressure than the first solvent.

The foregoing general description and the following detailed description are exemplary and explanatory only and are not restrictive of the invention, as defined in the appended claims.

### BRIEF DESCRIPTION OF THE DRAWINGS

The accompanying figures are included to improve understanding of concepts as presented herein.

FIG. 1 includes a diagram illustrating contact angle.

FIG. 2 includes an illustration of advancing and receding contact angles.

FIG. 3 includes a graph of contact angle with time.

FIG. 4 includes an illustration of one example of an organic electronic device.

Skilled artisans appreciate that objects in the figures are illustrated for simplicity and clarity and have not necessarily been drawn to scale. For example, the dimensions of some of the objects in the figures may be exaggerated relative to other objects to help to improve understanding of embodiments.

### DETAILED DESCRIPTION

Many aspects and embodiments have been described above and are merely exemplary and not limiting. After reading this specification, skilled artisans will appreciate that other aspects and embodiments are possible without departing from the scope of the invention.

Other features and benefits of any one or more of the embodiments will be apparent from the following detailed description, and from the claims. The detailed description first addresses Definitions and Clarification of Terms, followed by the Dynamic Receding Contact Angle Test, the Liquid Composition, the Electronic Device, and Examples.

### 1. DEFINITIONS AND CLARIFICATION OF TERMS

As used herein, the term “charge transport,” when referring to a layer, material, member, or structure is intended to mean such layer, material, member, or structure facilitates migration of such charge through the thickness of such layer, material, member, or structure with relative efficiency and small loss of charge. Hole transport materials facilitate positive charge; electron transport materials facilitate negative charge. Although photoactive materials may also have some charge transport properties, the term “charge, hole, or electron transport layer, material, member, or structure” is not intended to include a layer, material, member, or structure whose primary function is light emission or light reception.

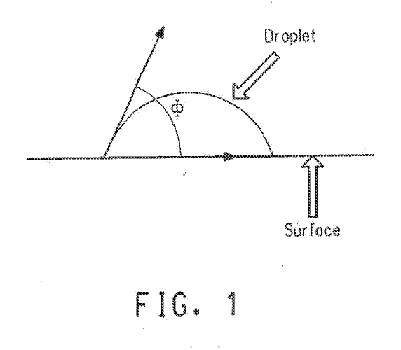

The term “contact angle” is intended to mean the angle φ shown in FIG. 1. For a droplet of liquid medium, angle φ is defined by the intersection of the plane of the surface and a line from the outer edge of the droplet to the surface. Furthermore, angle φ is measured after the droplet has reached an equilibrium position on the surface after being applied, i.e. “static contact angle”. A variety of manufacturers make equipment capable of measuring contact angles.

The terms “dewet” and other verb variants, refer to the retraction of a liquid film from its original coverage on an underlying layer.

The term “dispersion” refers to a continuous liquid medium containing a suspension of minute particles.

The term “electroactive” when referring to a layer or material, is intended to mean a layer or material that exhibits electronic or electro-radiative properties. In an electronic device, an electroactive material electronically facilitates the operation of the device. Examples of electroactive materials include, but are not limited to, materials which conduct, inject, transport, or block a charge, where the charge can be either an electron or a hole, and materials which emit radiation or exhibit a change in concentration of electron-hole pairs when receiving radiation. Examples of inactive materials include, but are not limited to, insulating materials and environmental barrier materials.

The term “layer” is used interchangeably with the term “film” and refers to a coating covering a desired area. The term is not limited by size. The area can be as large as an entire device or as small as a specific functional area such as the actual visual display, or as small as a single sub-pixel. Layers and films can be formed by any conventional deposition technique, including vapor deposition, liquid deposition (continuous and discontinuous techniques), and thermal transfer.

The term “liquid composition” is intended to mean a liquid medium in which a material is homogeneously distributed. In some embodiments, the material is dissolved in the liquid medium to form a solution. In some embodiment, the material is dispersed in the liquid medium to form a dispersion. In some embodiments, the material is suspended in the liquid medium to form a suspension or an emulsion.

The term “liquid medium” is intended to mean a liquid material, which can be a pure liquid or a combination of two or more liquids. Liquid medium is used regardless whether one or more liquids are present.

The term “neat form” as it refers to a liquid, is intended to mean that the liquid is not mixed with anything else.

The term “photoactive” is intended to mean a material that emits light when activated by an applied voltage (such as in a light emitting diode or chemical cell) or responds to radiant energy and generates a signal with or without an applied bias voltage (such as in a photodetector or a photovoltaic cell).

The terms “pin” or “pinning” and other verb variants, as they apply to a coated liquid composition, refer to the state in which the edge of the coated liquid composition does not retract substantially after being coated and during the drying process.

The term “solvent” is intended to mean a compound which is a liquid at room temperature. By room temperature, it is meant about 20° C.

The term “surface energy” is the energy required to create a unit area of a surface from a material. A characteristic of surface energy is that liquid materials with a given surface tension will not wet surfaces with a sufficiently lower surface energy. One way to determine the relative surface energies is to compare the contact angle of a given liquid on layers of different materials. The higher the contact angle, the lower the surface energy of the material and the lower wetting ability.

The term “surface tension” refers to the cohesive forces in a liquid, as measured in dyne/cm and is used to refer to the surface energy of a liquid. As the surface tension of liquids decreases, the liquids spread more readily over a surface.

The term “vapor pressure” refers to the equilibrium pressure of a vapor above its liquid. In some cases, the vapor pressure is measured in a closed container. In some cases, vapor pressure can be inferred from a measured evaporation rate in an open system.

The terms “wet” or “wetting” and other verb variants, as they apply to a coated liquid, refer to the spreading of the liquid over the surface to be coated. Liquids may wet spontaneously to form a thin film with a contact angle approaching zero, or they may wet partially, with a finite contact angle. From a practical standpoint, liquids that wet partially, with contact angle of about 10-20 degrees, can be considered to wet the surface. Liquids with significantly higher contact angles can be forced to form coated films by a coating or printing process, but they typically retract at the edges of the coating, or the edges of pinholes. Such liquids do not wet the surface, from a practical standpoint. This has been discussed in, for example, P-G. de Gennes et al, Capillarity and Wetting Phenomena: Drops, Bubbles, Pearl, Waves, Springer Science & Business Media (2004).

Unless otherwise defined, all technical and scientific terms used herein have the same meaning as commonly understood by one of ordinary skill in the art to which this invention belongs. Although methods and materials similar or equivalent to those described herein can be used in the practice or testing of embodiments of the present invention, suitable methods and materials are described below. All publications, patent applications, patents, and other references mentioned herein are incorporated by reference in their entirety, unless a particular passage is cited. In case of conflict, the present specification, including definitions, will control. In addition, the materials, methods, and examples are illustrative only and not intended to be limiting.

To the extent not described herein, many details regarding specific materials, processing acts, and circuits are conventional and may be found in textbooks and other sources within the organic light-emitting diode display, photodetector, photovoltaic, and semiconductive member arts.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. An alternative embodiment of the disclosed subject matter hereof, is described as consisting essentially of certain features or elements, in which embodiment features or elements that would materially alter the principle of operation or the distinguishing characteristics of the embodiment are not present therein. A further alternative embodiment of the described subject matter hereof is described as consisting of certain features or elements, in which embodiment, or in insubstantial variations thereof, only the features or elements specifically stated or described are present.

Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, use of the “a” or “an” are employed to describe elements and components of the invention. This is done merely for convenience and to give a general sense of the invention. This description should be read to include one or at least one and the singular also includes the plural unless it is obvious that it is meant otherwise.

### 2. DYNAMIC RECEDING CONTACT ANGLE TEST

In the production of electronic devices, it can be desirable to apply as many layers as possible by liquid deposition in order to reduce cost vs. applying the layers by a vacuum coating process. Liquid deposition techniques include but are not limited to, spin coating, gravure coating and printing, roll coating, curtain coating, dip coating, slot-die coating, doctor blade coating, spray coating, continuous nozzle coating, ink jet printing, and screen printing.

In some embodiments, a liquid composition is applied on an underlying layer where the liquid composition has a surface tension that is significantly higher than the surface energy of the underlying layer. The layer on which the liquid composition is to be applied is referred to herein as the “underlying layer”. In some embodiments, the underlying layer has a very low surface energy. In some embodiments, the liquid composition has a very high surface tension. In either case, there is a difference in surface energies.

There can be two resulting wetting problems:

1) initial wetting of the liquid composition on the underlying layer;

2) dewetting by the liquid composition to an undesired shape due to surface tension or drying stresses.

Initial wetting or spreading can be accomplished in at least two ways. First, the liquid medium can be selected to have a low enough surface tension so that it spreads spontaneously over the layer. Second, when the surface tension is not sufficiently low, the liquid composition can be spread by the liquid deposition process.

It has been found, that many desirable electroactive materials do not dissolve or disperse in solvents that spread spontaneously onto the desired underlying layers. In some cases, it is possible to formulate the compositions as dispersions in solvents that spread spontaneously. In some cases, it is not desirable to formulate dispersions. Preparing dispersions can be more costly than preparing solutions if intense mixing is required to disperse the ingredients. The dispersion may require surfactants or dispersant polymers to provide adequate shelf life and stability, adding additional cost. Surfactants and dispersants may need to be removed from the final electronic device (e.g., by baking) to avoid impacting device performance or lifetime.

Thus, in some embodiments, the liquid composition is formulated as a solution.

In some embodiments, initial spreading can be improved by using a first solvent in which the electroactive material is homogeneously distributed, and adding a solvent with low surface tension. This serves to reduce the overall surface tension of the liquid composition. However, these combinations of solvents may still not adequately wet the underlying layer and the liquid deposition process may be needed to improve wetting.

Spin coating is a liquid deposition process where spreading is accomplished simultaneously with drying. Such a process can accomplish acceptable coating. However, it is currently practical only in the laboratory and not in production where displays and lighting panels are to be prepared on large glass substrates, continuous plastic films, non-planar objects, etc. In the production process a liquid composition is applied by coating (e.g., slot coating, roll coating, spray coating), or printing (e.g., ink jet printing, continuous nozzle printing). Some of these techniques can force the liquid to spread on the underlying layer by applying the fluid with sufficient inertia. Others rely on forming a so-called coating bead where the liquid is held by surface tension between the coating applicator (e.g., slot die, roll) and the underlying layer. The coating bead allows applying the liquid composition in a stable shape.

These printing and coating processes may, or may not, form a desired initial liquid deposition depending on many factors—operating parameters (temperature, air flow rate above the substrate, flow rate, head speed, gap to substrate, proximity of applied droplets, gravure cell design, die lip design, etc.), fluid properties (surface tension, viscosity, solvent evaporation rate, etc.), and interaction with the surface. The final shape is determined by the region covered by liquid, and the thickness profile. The thickness profile will change during drying. Only the extent of liquid coverage will be considered here.

Examples of desired coverage are continuous, uniform sheets by coating, discrete regions and lines by printing, etc. In all cases, the desired shape requires the fluid have a desired extent, often defined by the die slot opening, the pattern of cells on a gravure roll, the pattern of raised dots on a flexographic plate, the pattern of wetting and non-wetting patches on a lithographic plate, the region addressed by a spray coating applicator (a region which may be defined by a mask), the drop pattern applied by ink jet printing, the pixel region defined by physical or surface tension boundaries, etc.

If the liquid deposition method does succeed in applying the liquid in the desired shape, then the second wetting problem identified above must be solved: the fluid must not retract an undesirable amount due to surface tension, or due to drying stresses. That is, the fluid must maintain the desired coverage and not dewet.

In practice, it has been found that the second wetting problem, the problem of retraction, is more difficult to solve. Many liquid compositions can be coated successfully to make uniform wet films with the desired coverage. However, some liquid compositions, once deposited, then retract at the edges due to interactions with the underlying layer surface. These interactions have often been thought of as a mismatch in surface tension of the liquid composition/surface energy of the underlying layer, where the liquid surface tension is too high vs. the underlying layer surface energy

It was desired to develop a rapid screening test for evaluating materials that may lead to less retraction. The contact angle (CA) of a liquid on a surface can provide information about the interaction with the surface, the tendency to spread or retract, etc. The static CA gives information on the balance of forces at equilibrium. The advancing and receding CA give additional information on interactions between the liquid and surface, often by observation of the stick-slip nature of liquid movement, by measurement of CA hysteresis, and in the case of the receding CA, the ability of the liquid to “pin” on the surface.

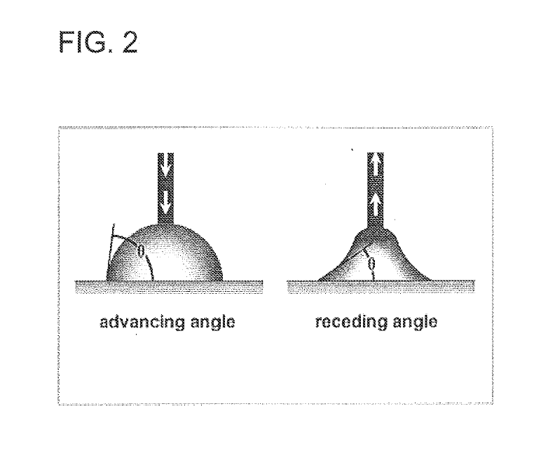

The standard test method for determining the receding CA is to withdraw liquid from a sessile drop on the surface. Such methods have been described, for example, by Ramé-Hart. The study requires adding volume to the drop dynamically to the maximum volume permitted without increasing the interfacial area between the liquid and solid phases. The resulting contact angle is referred to as the advancing angle, as illustrated in FIG. 2. Volume is then removed from the drop. When the maximum volume that can be removed without reducing the solid/liquid interface is reached, the resulting contact angle is measured. This angle is the receding angle, as illustrated in FIG. 2. When the receding angle is subtracted from the advancing angle, the result is called the contact angle hysteresis. The hysteresis characterizes surface topology and can help quantify contamination, surface chemical heterogeneity, and the effect of surface treatments, surfactants and other solutes. The advancing and receding angle can also be measured using the Ramé-Hart Tilting Base option.

In the standard test the liquid is withdrawn from the surface via a needle. Another method is to allow a droplet to ‘slide’ down a surface and measure the advancing and receding CA at the leading and trailing contact regions, respectively. The sliding drop technique has several drawbacks: the drop must be large enough for gravity to drive its motion; it is difficult to control and reproduce the drop movement; capturing images for drop shape analysis is more difficult with larger, moving drops.

It has been found, that the above test could not predict pinning behavior adequately. In the Ramé-Hart procedure the liquid adheres to the needle by surface tension. The presence of the needle prevents the liquid from receding naturally. Additionally, only a small amount of liquid—approximately, 20-30 μL—can be added to a drop while keeping the drop small enough to capture and analyze its shape using the high-resolution video system.

The standard advancing and receding CA tests described are often modified by adding (removing) substantial amounts of liquid to (from) the drop, and measuring the CA of the resulting drop shapes, either at rest or while moving.

While the tests above can often provide reproducible advancing and receding CA, we did not find a correlation between the results and the appearance of coatings. The tests were not predictive.

The dynamic receding contact angle test was developed to address the above deficiencies. All tests were performed on a Ramé-Hart model 500 goniometer. Video recordings were captured during the test, and the provided DropImage software was used to analyze the results.

The dynamic receding contact angle test has the following steps.

1) The needle is initially seen in the video display, and a small drop is applied to allow setting the cursors used for image capture and analysis. In some embodiments, the small drop is 1-5 μL; in some embodiments, 2 μL.
2) The needle is moved off-camera to provide more area on the video for the drop. The edge of the initial drop is still visible; this is apparently required for the image analysis software to start reliably. Data collection is initialized at a high rate. In some embodiments, the rate is 0.2 sec/point.
3) A large volume of fluid is ejected from the needle. In some embodiments the volume is 100-200 μL; in some embodiments 150-200 μL; in some embodiments 150 μL. The shadow of the liquid meniscus moves across the video region. When such a large amount of liquid is applied the free surface is quite large, and small waves or oscillations can often be seen on the free surface of a static drop, suggesting it is less influenced by the presence of the needle. The drop is large enough that wetting the needle does not prevent free retraction of the drop edge.
4) Immediately after filling the drop the pump is reversed and the liquid is drained off the surface as rapidly as the pump can withdraw the liquid. The liquid shadow reverses its course across the video screen. This rapid retraction simulates retraction at the edge of a liquid coating, and the large drop volume allows the edge to adjust its position independent of wetting the needle.

In some embodiments, the test is conducted with an initial drop of 2 μL in step 1; a data collection rate of 0.2 sec/point in step 2; and a large volume injection of 150 μL in step 3.

The video output shows receding contact angle with time. The results show clearly whether the liquid retracts off the surface or pins at the edge as the drop drains. When the liquid retracts off the surface, the receding CA has an essentially constant value with time. When the liquid pins, the image analysis software reports a dramatic reduction of CA to a very low value after which the data become unreliable.

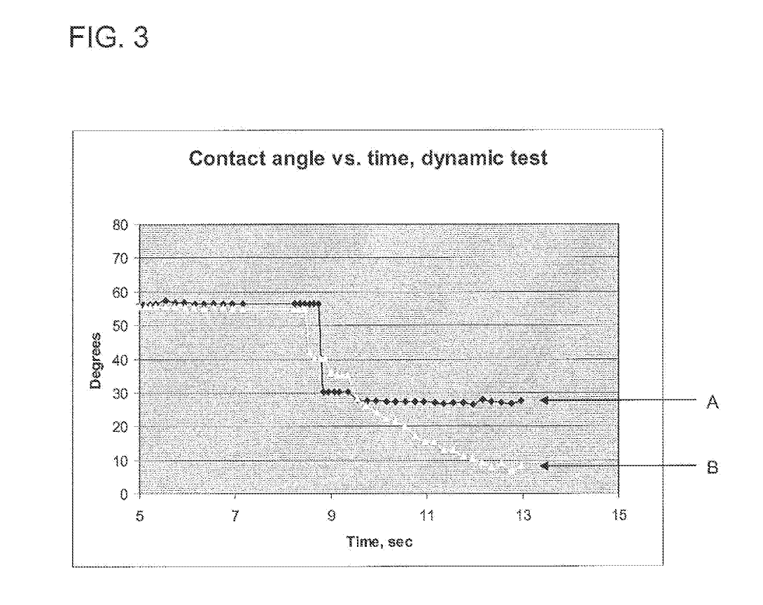

This is illustrated in FIG. 3. Line A shows the results from a liquid which retracts from the surface. The receding CA is high and stable with time. Line B shows the results from a liquid which pins at the edges of the surface. The receding CA is low and declining.

Sometimes the receding CA determined by the DropImage software suggests the liquid pins on the surface. It is necessary to confirm this by examining the video of the drop retraction. The software is less reliable when the liquid's viscosity is greater than about 10 centipoise.

The dynamic receding contact angle test is a fast and effective method to determine which liquid compositions will pin on a given surface, and thus will effectively coat the surface.

### 3. LIQUID COMPOSITION

The liquid composition is provided for liquid deposition onto an underlying layer. As used herein, “deposition onto” is intended to mean that the liquid composition is deposited directly on and in contact with the underlying layer.

The liquid composition comprises at least one organic electroactive material and a liquid medium. The liquid medium comprises (a) at least 20% by volume, based on the total volume of the liquid medium, of a first solvent and (b) at least 1% by volume, based on the total volume of the liquid medium, of a liquid organic additive, and wherein the liquid medium pins on the underlying layer as determined by a dynamic receding contact angle test and the first solvent does not pin on the underlying layer as determined by the test.

The exact nature of the electroactive material will depend on the intended use. In some embodiments, the materials are used in an organic light-emitting diode device or photovoltaic cell. Examples of electroactive materials that can be used for these devices include, but are not limited to, hole injection materials, hole transport materials, photoactive materials, photoactive materials and host materials, and electron transport materials.

The dynamic receding contact angle test determines if the liquid medium retracts and dewets, the second wetting problem identified above. The first wetting problem is addressed by the choice of liquid deposition method. Some deposition methods are more sensitive to surface energy differences than others and are less effective at forcing liquid compositions to spread. Thus, for successful deposition and film formation, the liquid medium should cover the underlying layer in the desired shape when applied by the desired liquid deposition method. Examples of liquid deposition methods have been discussed above.

The liquid medium comprises at least 20% by volume of the first solvent, based on the total volume of the liquid medium. In some embodiments, the liquid medium comprises at least 30% by volume of the first solvent; in some embodiments, at least 40% by volume; in some embodiments, at least 50% by volume; in some embodiments, at least 60% by volume; in some embodiments, at least 70% by volume; in some embodiments, at least 80% by volume; in some embodiments, at least 90% by volume; in some embodiments, at least 95% by volume.

The first solvent is one which, when tested in neat form retracts and does not pin on the underlying layer as determined by the dynamic receding contact angle test. Thus, a liquid composition with just the electroactive material and the first solvent will not coat the underlying layer without retracting.

The first solvent is one in which the electroactive material can be homogeneously distributed.

In some embodiments, the electroactive material is dissolved by the first solvent to form a solution. In some embodiments, the first solvent dissolves sufficient electroactive material to form at least a 0.1% w/v solution; in some embodiments, at least a 1.0% w/v solution; in some embodiments, at least a 3.0% w/v solution; in some embodiments, at least a 5.0% w/v solution. In some embodiments, the first solvent is an organic solvent.

In some embodiments, the electroactive material is dispersed in the first solvent to form a dispersion. By this it is meant, that a dispersion of the electroactive material can be formed in the first solvent and is stable without settling over time. In some embodiments, the dispersion is stable for at least 24 hours. In some embodiments, the dispersing solvent is water or an organic solvent.

In some embodiments, the electroactive material is suspended in the first solvent to form a suspension or an emulsion.

The first solvent should have other properties that are appropriate for the desired liquid deposition method. The first solvent should have a vapor pressure such that the deposited composition can be dried within a reasonable time. The vapor pressure should not be so high that it evaporates during deposition leaving deposited electroactive material on the deposition applicator. This requires washing off the residues or mechanically wiping them off to prevent defect formation. In some embodiments, the first solvent has a first vapor pressure that is less than 300 Pa; in some embodiments, less than 200 Pa.

The first solvent has a first surface tension, a first vapor pressure, and a first viscosity.

When the underlying layer has low surface energy, the first solvent may be chosen to have a surface tension that is not so high as to make wetting of the underlying layer unduly difficult. In some embodiments, the first solvent has a first surface tension that is less than 50 dyne/cm; in some embodiments, less than 40 dyne/cm.

The liquid organic additive is added to the first solvent in order to facilitate the liquid deposition process. The liquid organic additive may be soluble in or miscible with the first solvent. The combination of the first solvent and the liquid organic additive results in a composition that pins on the underlying layer, as determined by the dynamic receding contact angle test.

The composition of the liquid organic additive will depend on the composition of the underlying layer, the first solvent, and the electroactive material. Which additives will be effective cannot be predicted by the solubility of the electroactive material in the additive, the additive's vapor pressure, surface tension, or viscosity, but, rather, can be determined by the dynamic receding contact angle test.

The liquid organic additive is present at a level of at least 1% by volume, based on the total volume of the liquid medium. The upper limit for the amount of the liquid organic additive is not restricted by the dynamic receding contact angle test. As more liquid organic additive is added, the liquid medium will continue to pin on the underlying layer. However, other properties need to be taken into consideration. At some higher concentrations, the liquid organic additive may attack the underlying layer, cause the organic electroactive material to come out of solution or dispersion, or otherwise adversely affect the organic electroactive material. In some embodiments, the liquid organic additive is present at a level of 1-20% by volume; in some embodiments, 1-10% by volume; in some embodiments, 3-10% by volume; in some embodiments, 3-5% by volume.

In some embodiments, the liquid organic additive is a liquid which, in neat form is capable of damaging the underlying layer. By “damaging” it is meant that the liquid causes defects in the underlying layer. In some embodiments, the liquid organic additive in neat form is capable of dissolving or swelling the underlying layer. This can be determined by treating the underlying layer with the neat liquid organic additive and then visually inspecting the surface of the resulting layer. If the underlying layer is damaged by the liquid organic additive, the surface will have visible defects. In some cases, the surface will be rippled; in some cases, the surface will be pitted.

In some embodiments, the liquid medium further comprises (c) 5-70% by volume, based on the total volume of the liquid medium, of a second solvent which has a lower surface tension than the first solvent. In some embodiments, the second solvent is present at a level of 10-60% by volume; in some embodiments, 30-60% by volume.

In some embodiments, the second solvent is an organic solvent. In some embodiments, the second solvent reduces the surface tension and advancing contact angle of the liquid composition. Thus, the second solvent can facilitate the wetting of the underlying layer to cover the underlying layer in the desired shape when applied by the desired liquid deposition method.

The second solvent may or may not be capable of dissolving the electroactive material. However, the second solvent can be miscible with the first solvent and not cause the electroactive material to precipitate out of solution. The second solvent can also be miscible with the liquid organic additive.

In some embodiments, the liquid medium further comprises (d) 0.5-10% by volume, based on the total volume of the liquid medium, of a third solvent. The third solvent has a third vapor pressure which is lower than the first vapor pressure of the first solvent. In some embodiments, the third vapor pressure is less than 40 Pa; in some embodiments, less than 30 Pa; in some embodiments, less than 20 Pa; in some embodiments, less than 10 Pa. In some embodiments, the third solvent is an organic solvent.

In some embodiments, when the liquid composition is a solution, the third solvent is a solvent which is capable of dissolving the organic electroactive material. In some embodiments, the third solvent is chosen to be the last material in the liquid composition to evaporate out and maintains the solids in solution until the end of the drying process. In addition, in some embodiments, the third solvent helps prevent solution residues from hardening on the liquid deposition apparatus.

One skilled in the art will recognize a number of factors must be considered in selecting the solvents and the additive to achieve acceptable drying of the liquid deposition. For example, certain combinations of surface tensions, viscosities, and vapor pressures can lead to undesirable fluid motion driven by surface tension gradients as the liquid composition changes during drying (so-called Marangoni flows). It is clearly not the goal of this invention to address this type of defect. Useful guidance in this respect can be found in the literature, for example, T. C. Patton, Paint Flow and Pigment Dispersion, 2^{nd} ed., John Wiley & Sons, 1979.

In some embodiments, when the liquid composition is a dispersion, a suspension, or an emulsion, the third solvent is a solvent which is capable of maintaining the organic electroactive material in the dispersed, suspension, or emulsion form. In some embodiments, the third solvent may act to lessen or prevent solution residues from hardening on the liquid deposition apparatus.

In some embodiments, the liquid medium consists essentially of (a) 90-99% by volume, based on the total volume of the liquid medium, of the first solvent and (b) 1-10% by volume, based on the total volume of the liquid medium, of the liquid organic additive. In some embodiments, the liquid medium consists essentially of (a) 40-60% by volume, based on the total volume of the liquid medium, of the first solvent, (b) 1-10% by volume, based on the total volume of the liquid medium, of the liquid organic additive, and (c) 40-60% by volume, based on the total volume of the liquid medium, of the second solvent. In some embodiments, the liquid medium consists essentially of (a) 40-60% by volume, based on the total volume of the liquid medium, of the first solvent, (b) 3-5% by volume, based on the total volume of the liquid medium, of the liquid organic additive, and (c) 40-60% by volume, based on the total volume of the liquid medium, of the second solvent. In some embodiments, the liquid medium consists essentially of (a) 40-60% by volume, based on the total volume of the liquid medium, of the first solvent, (b) 1-10% by volume, based on the total volume of the liquid medium, of the liquid organic additive, (c) 40-60% by volume, based on the total volume of the liquid medium, of the second solvent, and (d) 0.5-10% by volume, based on the total volume of the liquid medium, of the third solvent. In some embodiments, the liquid medium consists essentially of (a) 40-60% by volume, based on the total volume of the liquid medium, of the first solvent, (b) 3-5% by volume, based on the total volume of the liquid medium, of the liquid organic additive, (c) 40-60% by volume, based on the total volume of the liquid medium, of the second solvent, and (d) 1-3% by volume, based on the total volume of the liquid medium, of the third solvent.

In some embodiments, there can be any combination of the above embodiments, so long as they are not mutually exclusive.

### 4. ELECTRONIC DEVICE

In some embodiments, the liquid compositions described herein are useful for liquid deposition of one or more layers in an organic electronic device.

The term “organic electronic device” is intended to mean a device including one or more organic semiconductor layers or materials. Organic electronic devices include, but are not limited to: (1) devices that convert electrical energy into radiation (e.g., a light-emitting diode, light emitting diode display, diode laser, or lighting panel), (2) devices that detect signals through electronic processes (e.g., photodetectors photoconductive cells, photoresistors, photoswitches, phototransistors, phototubes, infrared (“IR”) detectors, or biosensors), (3) devices that convert radiation into electrical energy (e.g., a photovoltaic device or solar cell), and (4) devices that include one or more electronic components that include one or more organic semiconductor layers (e.g., a transistor or diode). The term device also includes coating materials for memory storage devices, antistatic films, biosensors, electrochromic devices, solid electrolyte capacitors, energy storage devices such as a rechargeable battery, and electromagnetic shielding applications.

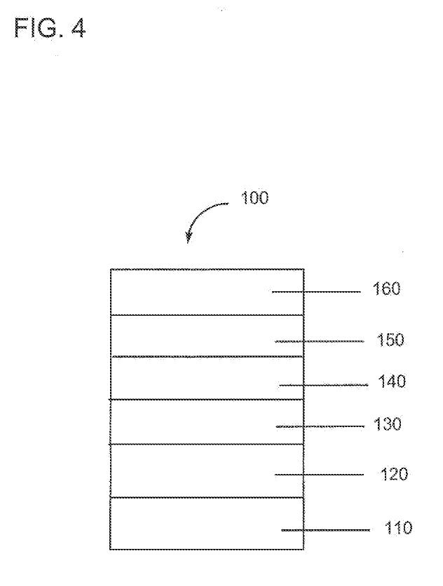

FIG. 4 is an exemplary electronic device, an organic light-emitting diode (OLEO) display that includes at least two organic electroactive layers positioned between two electrical contact layers. The electronic device 100 includes one or more layers 120 and 130 to facilitate the injection of holes from the anode layer 110 into the photoactive layer 140. In general, when two layers are present, the layer 120 adjacent the anode is called the hole injection layer. The layer 130 adjacent to the photoactive layer is called the hole transport layer. An optional electron transport layer 150 is located between the photoactive layer 140 and a cathode layer 160. The organic layers 120 through 150 are individually and collectively referred to an the organic electroactive layers of the device. Depending on the application of the device 100, the photoactive layer 140 can be a light-emitting layer that is activated by an applied voltage (such as in a light-emitting diode or light-emitting electrochemical cell), a layer of material that responds to radiant energy and generates a signal with or without an applied bias voltage (such as in a photodetector or photovoltaic cell). For multicolor devices, the photoactive layer 140 is made up different areas of two or more different colors. The device is not limited with respect to system, driving method, and utility mode. A priming layer is not shown in this diagram.

The layers in the device can be made of any materials which are known to be useful in such layers. The device may include a support or substrate (not shown) that can be adjacent to the anode layer 110 or the cathode layer 160. In a conventional structure, the support is adjacent the anode. For the conventional structure the device will be formed by applying the anode layer first, then layers 120, 130, 140, 150, and 160, in that order. In an inverted structure, the support is adjacent the cathode. For the inverted structure, the device will be formed by applying the cathode layer first, then layers 150, 140, 130, 120, and 110, in that order. Most frequently, the support is adjacent the anode layer 110. The support can be flexible or rigid, organic or inorganic. Generally, glass or flexible organic films are used as a support.

The anode layer 110 is an electrode that is more efficient for injecting holes compared to the cathode layer 160. The anode can include materials containing a metal, mixed metal, alloy, metal oxide or mixed oxide. Suitable materials include the mixed oxides of the Group 2 elements (i.e., Be, Mg, Ca, Sr, Ba), the Group 11 elements, the elements in Groups 4, 5, and 6, and the Group 8-10 transition elements. If the anode layer 110 is to be light transmitting, mixed oxides of Groups 12, 13 and 14 elements, such as indium-tin-oxide, may be used. As used herein, the phrase “mixed oxide” refers to oxides having two or more different cations selected from the Group 2 elements or the Groups 12, 13, or 14 elements. Some non-limiting, specific examples of materials for anode layer 110 include, but are not limited to, indium-tin-oxide (“ITO”), aluminum-tin-oxide, aluminum-zinc-oxide, gold, silver, copper, and nickel. The anode may also comprise an organic material such as polyaniline, polythiophene, or polypyrrole.

The anode layer 110 may be formed by a chemical or physical vapor deposition process or spin-cast process. Chemical vapor deposition may be performed as a plasma-enhanced chemical vapor deposition (“PECVD”) or metal organic chemical vapor deposition (“MOCVD”). Physical vapor deposition can include all forms of sputtering, including on beam sputtering, as well as e-beam evaporation and resistance evaporation. Specific forms of physical vapor deposition include rf magnetron sputtering and inductively-coupled plasma physical vapor deposition (“IMP-PVD”). These deposition techniques are well known within the semiconductor fabrication arts.

Usually, the anode layer 110 is patterned during a lithographic operation. The pattern may vary as desired. The layers can be formed in a pattern by, for example, positioning a patterned mask or resist on the first flexible composite barrier structure prior to applying the first electrical contact layer material. Alternatively, the layers can be applied as an overall layer (also called blanket deposit) and subsequently patterned using, for example, a patterned resist layer and wet chemical or dry etching techniques. Other processes for patterning that are well known in the art can also be used. When the electronic devices are located within an array, the anode layer 110 typically is formed into substantially parallel strips having lengths that extend in substantially the same direction.

The hole injection layer 120 functions to facilitate injection of holes into the photoactive layer and to planarize the anode surface to prevent shorts in the device. Hole injection materials may be polymers, oligomers, or small molecules, and may be in the form of solutions, dispersions, suspensions, emulsions, colloidal mixtures, or other compositions.

The hole injection layer can be formed with polymeric materials, such as polyaniline (PAM) or polyethylenedioxythiophene (PEDOT), which are often doped with protonic acids. The protonic acids can be, for example, poly(styrenesulfonic acid), poly(2-acrylamido-2-methyl-1-propanesulfonic acid), and the like. The hole injection layer 120 can comprise charge transfer compounds, and the like, such as copper phthalocyanine and the tetrathiafulvalene-tetracyanoquinodimethane system (TTF-TCNQ). In some embodiments, the hole injection layer 120 is made from a dispersion of a conducting polymer and a colloid-forming polymeric acid.

In some embodiments, the hole injection layer comprises a conductive polymer doped with a fluorinated acid polymer. In some embodiments, the hole injection layer consists essentially of a conductive polymer doped with a fluorinated acid polymer. In some embodiments, the hole injection layer consists essentially of a conductive polymer doped with a fluorinated acid polymer and inorganic nanoparticles. In some embodiments, the inorganic nanoparticles are selected from the group consisting of silicon oxide, titanium oxides, zirconium oxide, molybdenum trioxide, vanadium oxide, aluminum oxide, zinc oxide, samarium oxide, yttrium oxide, cesium oxide, cupric oxide, stannic oxide, antimony oxide, and combinations thereof. Such materials have been described in, for example, published U.S. patent applications US 2004/0102577, US 2004/0127637, US 2005/0205860, and published PCT application WO 2009/018009.

The hole injection layer 120 can be applied by any deposition technique. In some embodiments, the hole injection layer is applied by a solution deposition method, as described above. In some embodiments, the hole injection layer is applied by a continuous solution deposition method.

Layer 130 comprises hole transport material. Examples of hole transport materials for the hole transport layer have been summarized for example, in Kirk-Othmer Encyclopedia of Chemical Technology, Fourth Edition, Vol, 18, p. 837-860, 1996, by Y. Wang. Both hole transporting small molecules and polymers can be used. Commonly used hole transporting molecules include, but are not limited to: 4,4′,4″-tris(N,N-diphenyl-amino)-triphenylamine (TDATA); 4,4′,4″-tris(N-3-methylphenyl-N-phenyl-amino)-triphenylamine (MTDATA); N,N′-diphenyl-N,N′-bis(3-methylphenyl)-[1,1′-biphenyl]-4,4′-diamine (TPD); 4,4′-bis(carbazol-9-yl)biphenyl (CBP); 1,3-bis(carbazol-9-yl)benzene (mCP); 1,1-bis[(di-4-tolylamino)phenyl]cyclohexane (TAPC); N,N′-bis(4-methylphenyl)-N,N′-bis(4-ethylphenyl)-[1,1′-(3,3′-dimethyl)biphenyl]-4,4′-diamine (ETPD); tetrakis-(3-methylphenyl)-N,N,N′,N′-2,5-phenylenediamine (PDA); α-phenyl-4-N,N-diphenylaminostyrene (TPS); p-(diethylamino)benzaldehyde diphenylhydrazone (DEH); triphenylamine (TPA); bis[4-(N,N-diethylamino)-2-methylphenyl](4-methylphenyl)methane (MPMP); 1-phenyl-3-[p-(diethylamino)styryl]-5-[p-(diethylamino)phenyl]pyrazoline (PPR or DEASP); 1,2-trans-bis(9H-carbazol-9-yl)cyclobutane (DCZB); N,N,N′,N′-tetrakis(4-methylphenyl)-(1,1′-biphenyl)-4,4′-diamine (TTB); N,N′-bis(naphthalen-1-yl)-N,N′-bis-(phenyl)benzidine (α-NPB); and porphyrinic compounds, such as copper phthalocyanine. Commonly used hole transporting polymers include, but are not limited to, polyvinylcarbazole, (phenylmethyl)polysilane, poly(dioxythiophenes), polyanilines, and polypyrroles. It is also possible to obtain hole transporting polymers by doping hole transporting molecules such as those mentioned above into polymers such as polystyrene and polycarbonate.

In some embodiments, the hole transport layer comprises a hole transport polymer. In some embodiments, the hole transport polymer is a distyrylaryl compound. In some embodiments, the aryl group is has two or more fused aromatic rings. In some embodiments, the aryl group is an acene. The term “acene” as used herein refers to a hydrocarbon parent component that contains two or more ortho-fused benzene rings in a straight linear arrangement.

In some embodiments, the hole transport polymer is an arylamine polymer. In some embodiments, it is a copolymer of fluorene and arylamine monomers.

In some embodiments, the polymer has crosslinkable groups. In some embodiments, crosslinking can be accomplished by a heat treatment and/or exposure to UV or visible radiation. Examples of crosslinkable groups include, but are not limited to vinyl, acrylate, perfluorovinylether, 1-benzo-3,4-cyclobutane, siloxane, and methyl esters. Crosslinkable polymers can have advantages in the fabrication of solution-process OLEDs. The application of a soluble polymeric material to form a layer which can be converted into an insoluble film subsequent to deposition, can allow for the fabrication of multilayer solution-processed OLED devices free of layer dissolution problems.

Examples of crosslinkable polymers can be found in, for example, published US patent application 2005/0184287 and published POT application WO 2005/052027.

In some embodiments, the hole transport layer comprises a polymer which is a copolymer of 9,9-dialkylfluorene and triphenylamine. In some embodiments, the polymer is a copolymer of 9,9-dialkylfluorene and 4,4′-bis(diphenylamino)biphenyl. In some embodiments, the polymer is a copolymer of 9,9-dialkylfluorene and TPB. In some embodiments, the polymer is a copolymer of 9,9-dialkylfluorene and NPB. In some embodiments, the copolymer is made from a third comonomer selected from (vinylphenyl)diphenylamine and 9,9-distyrylfluorene or 9,9-di(vinylbenzyl)fluorene. In some embodiments, the hole transport layer comprises a material comprising triarylamines having conjugated moieties which are connected in a non-planar configuration. Such materials can be monomeric or polymeric. Examples of such materials have been described in, for example, published POT application WO 2009/067419.

In some embodiments, the hole transport layer is doped with a p-dopant, such as tetrafluorotetracyanoquinodimethane and perylene-3,4,9,10-tetracarboxylic-3,4,9,10-dianhydride.

The hole transport layer 130 can be applied by any deposition technique. In some embodiments, the hole transport layer is applied by a solution deposition method, as described above. In some embodiments, the hole transport layer is applied by a continuous solution deposition method.

Depending upon the application of the device, the photoactive layer 140 can be a light-emitting layer that is activated by an applied voltage (such as in a light-emitting diode or light-emitting electrochemical cell), a layer of material that responds to radiant energy and generates a signal with or without an applied bias voltage (such as in a photodetector). In some embodiments, the photoactive material is an organic electroluminescent (“EL”) material. Any EL material can be used in the devices, including, but not limited to, small molecule organic fluorescent compounds, fluorescent and phosphorescent metal complexes, conjugated polymers, and mixtures thereof. Examples of fluorescent compounds include, but are not limited to, chrysenes, pyrenes, perylenes, rubrenes, coumarins, anthracenes, thiadiazoles, derivatives thereof, and mixtures thereof. Examples of metal complexes include, but are not limited to, metal chelated oxinoid compounds, such as tris(8-hydroxyquinolato)aluminum (Alq3): cyclometalated iridium and platinum electroluminescent compounds, such as complexes of iridium with phenylpyridine, phenylquinoline, or phenylpyrimidine ligands as disclosed in Petrov et al., U.S. Pat. No. 6,670,645 and Published PCT Applications WO 03/063555 and WO 2004/016710, and organometallic complexes described in, for example, Published PCT Applications WO 03/008424, WO 03/091688, and WO 03/040257, and mixtures thereof. In some cases the small molecule fluorescent or organometallic materials are deposited as a dopant with a host material to improve processing and/or electronic properties. Examples of conjugated polymers include, but are not limited to poly(phenylenevinylenes), polyfluorenes, poly(spirobifluorenes), polythiophenes, poly(p-phenylenes), copolymers thereof, and mixtures thereof.

The photoactive layer 140 can be applied by any deposition technique. In some embodiments, the photoactive layer is applied by a solution deposition method, as described above. In some embodiments, the photoactive layer is applied by a continuous solution deposition method.

Optional layer 150 can function both to facilitate electron transport, and also serve as a buffer layer or confinement layer to prevent quenching of the exciton at layer interfaces. Preferably, this layer promotes electron mobility and reduces exciton quenching. Examples of electron transport materials which can be used in the optional electron transport layer 150, include metal chelated oxinoid compounds, including metal quinolate derivatives such as tris(8-hydroxyquinolato)aluminum (AlQ), bis(2-methyl-8-quinolinolato)(p-phenylphenolato) aluminum (BAlq), tetrakis-(8-hydroxyquinolato)hafnium (HfQ) and tetrakis-(8-hydroxyquinolato)zirconium (ZrQ); and azole compounds such as 2-(4-biphenylyl)-5-(4-t-butylphenyl)-1,3,4-oxadiazole (PBD), 3-(4-biphenylyl)-4-phenyl-5-(4-t-butylphenyl)-1,2,4-triazole (TAZ), and 1,3,5-tri(phenyl-2-benzimidazole)benzene (TPBI); quinoxaline derivatives such as 2,3-bis(4-fluorophenyl)quinoxaline; phenanthrolines such as 4,7-diphenyl-1,10-phenanthroline (DPA) and 2,9-dimethyl-4,7-diphenyl-1,10-phenanthroline (DDPA); and mixtures thereof. In some embodiments, the electron transport layer further comprises an n-dopant. N-dopant materials are well known. The n-dopants include, but are not limited to. Group 1 and 2 metals; Group 1 and 2 metal salts, such as LiF, CsF, and Cs₂CO₃; Group 1 and 2 metal organic compounds, such as Li quinolate; and molecular n-dopants, such as leuco dyes, metal complexes, such as W₂(hpp)₄ where hpp=1,3,4,6,7,8-hexahydro-2H-pyrimido-[1,2-a]-pyrimidine and cobaltocene, tetrathianaphthacene, bis(ethylenedithio)tetrathiafulvalene, heterocyclic radicals or diradicals, and the dimers, oligomers, polymers, dispiro compounds and polycycles of heterocyclic radical or diradicals.

The electron transport layer 150 is usually formed by a chemical or physical vapor deposition process.

The cathode 160, is an electrode that is particularly efficient for injecting electrons or negative charge carriers. The cathode can be any metal or nonmetal having a lower work function than the anode. Materials for the cathode CaO be selected from alkali metals of Group 1 (e.g., Li, Cs), the Group 2 (alkaline earth) metals, the Group 12 metals, including the rare earth elements and lanthanides, and the actinides. Materials such as aluminum, indium, calcium, barium, samarium and magnesium, as well as combinations, can be used. Li-containing organometallic compounds, LiF, Li₂O, Cs-containing organometallic compounds, CsF, Cs₂O, and Cs₂CO₃ can also be deposited between the organic layer and the cathode layer to lower the operating voltage. This layer may be referred to as an electron injection layer.

The cathode layer 160 is usually formed by a chemical or physical vapor deposition process.

In some embodiments, additional layers(s) may be present within organic electronic devices. It is understood that each functional layer can be made up of more than one layer.

In some embodiments, a priming layer is present directly over the hole injection layer. The priming layer is a patterned layer that has a surface energy that is higher than the surface energy of the hole injection layer. The priming layer serves as a chemical containment layer. The term “contained” when referring to a layer, is intended to mean that as the layer is applied by liquid deposition, it does not spread significantly beyond the area where it is deposited despite a natural tendency to do so were it not contained. With “chemical containment” the layer is contained by surface energy effects. The hole transport layer is formed by liquid deposition over and on the pattern of priming layer on the hole injection layer. Priming layers have been described in copending patent application published as PCT application WO 2011-014216.

In some embodiments, the priming layer reacts with the underlying area when exposed to radiation. The exact mechanism of this reaction will depend on the materials used. After exposure to radiation, the priming layer is effectively removed in the unexposed areas by a suitable development treatment. In some embodiments, the priming layer is removed only in the unexposed areas. In some embodiments, the priming layer is partially removed in the exposed areas as well, leaving a thinner layer in those areas. In some embodiments, the priming layer that remains in the exposed areas is less than 50 Å in thickness. In some embodiments, the priming layer that remains in the exposed areas is essentially a monolayer in thickness.

In some embodiments, the priming layer comprises a hole transport material. In some embodiments, the priming layer comprises a material selected from the group consisting of triarylamines, carbazoles, fluorenes, polymers thereof, copolymers thereof, deuterated analogs thereof, and combinations thereof. In some embodiments, the priming layer comprises a material selected from the group consisting of polymeric triarylamines, polycarbazoles, polyfluorenes, polymeric triarylamines having conjugated moieties which are connected in a non-planar configuration, copolymers of fluorene and triarylamine, deuterated analogs thereof, and combinations thereof. In some embodiments, the polymeric materials are crosslinkable. In some embodiments, the priming layer comprises an electron transport material. In some embodiments, the priming layer comprises a metal chelated oxinoid compound. In some embodiments, the priming layer comprises a metal quinolate derivative. In some embodiments, the priming layer comprises a material selected from the group consisting of tris(8-hydroxyquinolato)aluminum, bis(2-methyl-8-quinolinolato)(p-phenylphenolato) aluminum, tetrakis-(8-hydroxyquinolato)hafnium, and tetrakis-(8-hydroxyquinolato)zirconium. In some embodiments, the priming layer consists essentially of a material selected from the group consisting of polymeric triarylamines, polycarbazoles, polyfluorenes, copolymers thereof, and metal quinolates.

In some embodiments, the different layers have the following range of thicknesses: anode 110, 100-5000 Å, In some embodiments 100-2000 Å; hole injection layer 120, 50-2500 Å, In some embodiments 200-1000 Å; hole transport layer 130, 50-2500 Å, In some embodiments 200-1000 Å; photoactive layer 140, 10-2000 Å, In some embodiments 100-1000 Å; electron transport layer 150, 50-2000 Å, In some embodiments 100-1000 Å; cathode 160, 200-10000 Å, In some embodiments 300-5000 Å. The desired ratio of layer thicknesses will depend on the exact nature of the materials used.

In some embodiments, the hole injection layer comprises a conductive polymer doped with a fluorinated sulfonic acid polymer. Such materials have been described in, for example, published U.S. patent applications 2004-0102577, 2004-0127637, and 2005-0205860 and published PCT application WO 2009/018009. These hole injection layers can have very low surface energy.

In some embodiments, the liquid compositions described herein are useful for liquid deposition over an underlying layer which is a hole injection layer comprising a conductive polymer doped with a fluorinated sulfonic acid polymer. This can be useful when the device has a conventional structure. In some embodiments, the electroactive material is a hole transport material. In some embodiments, the hole transport material is deposited to form a hole transport layer. In some embodiments, the hole transport material is deposited to form a priming layer. In some embodiments, the electroactive material is an electron transport material and is deposited to form a priming layer. The exact choice for first solvent, additive, and optional second and third solvents will depend on the composition of the electroactive material to be deposited. A suitable solvent for a particular compound or related class of compounds can be readily determined by one skilled in the art.

Suitable classes of solvents include, but are not limited to, aliphatic hydrocarbons (such as decane and hexadecane), halogenated hydrocarbons (such as methylene chloride, chloroform, chlorobenzene, and perfluoroheptane), aromatic hydrocarbons (such as non-substituted and alkyl- and alkoxy-substituted toluenes and xylenes), aromatic ethers (such as anisole and dibenzyl ether), heteroaromatics (such as pyridine) polar solvents (such as tetrahydropyran (“THP”), dimethylacetamide (“DMAC”) and N-methylpyrrolidone (“NMP”)), esters (such as ethylacetate and propylene carbonate), alcohols and glycols (such as isopropanol and ethylene glycol), glycol ethers and derivatives (such as propylene glycol methyl ether and propylene glycol methyl ether acetate), and ketones (such as cyclopentanone and diisobutyl ketone).

In some device embodiments using the above described liquid composition, the underlying layer comprises a conductive polymer doped with a fluorinated sulfonic acid polymer and the electroactive material in the liquid composition is hole transport material which is a small molecule, oligomer, or polymer with triarylamine functionality. By “triarylamine functionality” it is meant that the material has one or more triarylamine groups which have hole transport properties. Some examples of suitable first solvents for the liquid composition include, but are not limited to, aromatic ethers, such as 4-methylanisole and 3,4-dimethylanisole. Some examples of additives include, but are not limited to DMAC, NMP, pyridine, and propylene carbonate. Some examples of second solvents include, but are not limited to mesitylene, decane, 1-butanol, and propylene glycol propyl ether. Some examples of third solvents include, but are not limited to, cyclohexylbenzene and dibenzyl ether.

In some device embodiments, the liquid compositions described herein are useful for liquid deposition of electroactive material which is an electrically conductive doped with a fluorinated sulfonic acid polymer. In some embodiments, when the device has an inverted structure, the electroactive material is deposited to form a hole injection layer over an underlying layer comprising a hole transport material. In some embodiments, the liquid composition comprises a dispersion of an electrically conductive polymer doped with a fluorinated sulfonic acid polymer in a first solvent. In some embodiments, the first solvent is water. The water has very high surface tension compared to the surface energy of most hole transport material layers.

### EXAMPLES

The concepts described herein will be further described in the following examples, which do not limit the scope of the invention described in the claims.

### Materials

HIL-1 is a hole injection layer, and was formed from an aqueous dispersion of a conducting polymer doped with a fluorinated sulfonic acid polymer. Such materials have been described in, for example, published U.S. patent applications 2004-0102577, 2004-0127637, and 2005-0205860 and published POT application WO 2009-018009.
HT-1 is a hole transport material, which is a triarylamine polymer. Such materials have been described in, for example, published PCT application WO 2009/067419.

### Example 1

This example illustrates the use of the dynamic receding contact angle (“DRCA”) test to determine the retraction of solvents on a low surface energy layer.

A layer of HIL-1 was formed by slot coating an aqueous dispersion onto a glass substrate. The HIL-1 layer was baked at 70° C. for at least 1 minute before each test.

The neat solvents were tested for retraction on the HIL-1 surface. A 150-200 μL drop of each liquid was dynamically applied to the HIL-1 layer and withdrawn from the surface using a nominal 100 μm diameter syringe needle. Measurements were obtained on a Rame-Hart model 500 goniometer with DropImage Pro software. Data points were collected at 0.2 second intervals. Retraction was determined by examining the video recording.

The results are given in Table 1 below.

TABLE 1
Neat Solvent Results

| | | | DRCA |
|---|---|---|---|
| | Surface | Vapor | Results |
| Neat Solvents | Tension | Pressure | on HIL-1 |
| 1,2-dimetboxybenzene | 27.9 | 1170.1 | Pinned |
| 1,2-propanediol | 35.5 | 17.2 | Pinned |
| 1,3-propanediol | 45.7 | 5.8 | Pinned |
| 1,4-cineole | | 223.3 | Pinned |
| 1-butanol | 24.4 | 900.8 | Pinned |
| 2-ethylhexyl acetate | 26.7 | 42.2 | Pinned |
| diisobutyl ketone | 22.8 | 224.4 | Pinned |
| dimethylsulfoxide | 42.9 | 80.2 | Pinned |
| dipropylene glycol methyl ether | 28.8 | 37.3 | Pinned |
| ethylene glycol | 48.0 | 11.8 | Pinned |
| N,N-dimethylacetamide | 33.1 | 266.6 | Pinned |
| N-methyl pyrrolidone | 42.2 | 46.0 | Pinned |
| propylene carbonate | 41.1 | 6.6 | Pinned |
| propylene glycol methyl ether | 27.9 | 1608.7 | Pinned |
| propylene glycol methyl ether | 28.9 | 373.3 | Pinned |
| acetate | | | |
| propylene glycol n-propyl ether | 27.3 | 379.7 | Pinned |
| propylene glycol phenyl ether | 38.1 | 25.2 | Pinned |
| pyridine | 36.7 | 2771.7 | Pinned |
| pyrrole | 37.0 | 1096.5 | Pinned |
| tetrahydropyran | | | Pinned |
| 1,2-dimethylbenzene | | | Retracted |
| 1,3,5-trimeythylbenzene | 28.0 | 336.9 | Retracted |
| 1,4-dimethylbenzene | 27.9 | 1170.1 | Retracted |
| 1-methoxynapthalene | | | Retracted |
| 1-phenyloctane | 30.1 | 1.5 | Retracted |
| 3,4-dimethyl anisole | 27.0 | 47.8 | Retracted |
| 4-methyl anisole | 32.0 | 152.0 | Retracted |
| anisole | 27.0 | 47.8 | Retracted |
| cyclohexylbenzene | 34.6 | 6.8 | Retracted |
| decane | 22.4 | 181.0 | Retracted |
| dibenzyl ether | 39.8 | 0.1 | Retracted |
| diethyl phthalate | | | Retracted |
| diethylbenzene (mixed isomers) | | | Retracted |
| dimethyl phthalate | | | Retracted |
| hexadecane | 27.1 | 0.2 | Retracted |
| methyl benzoate | | | Retracted |

Surface tension is in dyne/cm; vapor pressure is in Pa

It can be seen from the above results that there is no correlation between surface tension and pinning.

### Example 2

This example illustrates a test for determining whether a solvent attacks the underlying layer.

Solvents that pinned may or may not attack the HIL-1 surface. Attacking the HIL-1 surface can lead to undesirable layer mixing, and/or deterioration of the HIL thickness uniformity.

A ca. 300 μL drop of solvent was applied to an HIL-1 surface for about 5 minutes, and then removed via syringe and/or wicking. The surface was dried on a 70° C. hot plate for at least 5 minutes, and examined visually for defects.

The results are given in Table 2 below.

TABLE 2
Surface Defects

| | HIL-1 |
|---|---|
| Neat solvents | Defects |
| 1,2-dimethoxybenzene | No |
| 1,2-propanediol | Yes |
| 1,3-propanediol | Yes |
| 1,4-cineole | Yes |
| 1-butanol | No |
| 2-ethylhexyl acetate | Yes |
| diisobutyl ketone | No |
| dimethylsulfoxide | Yes |
| dipropylene glycol methyl ether | No |
| ethylene glycol | Yes |
| N,N-dimethylacetamide | Yes |
| N-methyl pyrrolidone | Yes |
| propylene carbonate | Yes |
| propylene glycol methyl ether | Yes |
| propylene glycol methyl ether acetate | No |
| propylene glycol n-propyl ether | Yes |
| propylene glycol phenyl ether | No |
| pyridine | Yes |
| pyrrole | Yes |
| tetrahydropyran | Yes |

### Example 3

This example illustrates a test for determining whether a solvent attacks the underlying layer.

The procedure of Example 2 was repeated to test the solvents that retracted. The results are given in Table 3.

TABLE 3
Surface Defects

| | HIL-1 |
|---|---|
| Neat solvents | Defects |
| 1,2-dimethylbenzene | No |
| 1,3,5-trimeythylbenzene | No |
| 1-methoxynapthalene | No |
| 1-phenyloctane | No |
| 3,4-dimethyl anisole | No |
| 4-methyl anisole | No |
| anisole | No |
| cyclohexylbenzene | No |
| decane | No |
| dibenzyl ether | No |
| diethyl phthalate | No |
| diethylbenzene (mixed isomers) | No |
| dimethyl phthalate | No |
| hexadecane | No |
| methyl benzoate | No |

Of the solvents listed above as not causing HIL-1 defects, several were found to dissolve a sufficient concentration (0.5% weight polymer in volume of solvent) of HT-1 that was to be coated onto HIL-1. Of these, 4-methyl anisole was selected as having a practical vapor pressure for liquid deposition processes.

### Example 4

This example illustrates the formulation of the liquid medium for a practical coating composition. The liquid medium contains a first solvent and a liquid organic additive.

4-methyl anisole (“4MA”) was selected as a first solvent for HT-1. 4MA does not attack the HIL-1 surface and has a sufficiently low vapor pressure so that it does not dry out and/or leave residues on the coating applicator during normal liquid deposition operations.

Liquid media of 97% by volume 4MA were prepared containing 3% of a liquid to be tested as a potential liquid organic additive. This concentration was chosen to facilitate screening, other concentrations are acceptable. The additives to be tested were those solvents that did not retract on the HIL; regardless of whether the non-retracting solvent attacked the HIL.

These liquid media were tested using the dynamic receding contact angle test as described in Example 1. The results are given in Table 4 below.

TABLE 4
Liquid Media Results

| | DRCA Results |
|---|---|
| Additives at 3% V/V in 4MA | on HIL-1 |
| 1,2-dimethoxybenzene | Retracted |
| 1,2-propanediol | immiscible |
| 1,3-propanediol | immiscible |
| 1,4-cineole | Retracted |
| 1-butanol | Retracted |
| 2-ethylhexyl acetate | Retracted |
| diisobutyl ketone | Retracted |
| dimethylsulfoxide | Retracted |
| dipropylene glycol methyl ether | Retracted |
| ethylene glycol | immiscible |
| N,N-dimethylacetamide | Retracted |
| N-methyl pyrrolidone (NMP) | Pinned |
| propylene carbonate | Pinned |
| propylene glycol methyl ether | Retracted |
| propylene glycol methyl ether | Retracted |
| acetate | |
| propylene glycol n-propyl ether | Retracted |
| propylene glycol phenyl ether | Retracted |
| pyridine | Pinned |
| pyrrole | Retracted |
| tetrahydropyran | Retracted |

Of the additives in the list above, NMP, propylene carbonate, and pyridine were good candidates as the liquid organic additive when used at a level of 3% in a blend with 4MA. Other solvents and blends may be acceptable at different levels.

### Example 5

This example illustrates the formulation of a liquid composition with a hole transport material as the electroactive material onto HIL-1.

Liquid compositions containing 0.5% weight of HT-1 by volume of liquid medium were prepared using the formulations in Table 5. The liquid compositions were tested for retraction on the HIL surface by dynamic receding contact angle, as described in Example 1. The liquid composition were also coated over the HIL-1 surface using a doctor blade (Elcometer automated doctor blade coater, coating speed setting 3; doctor blade gap ˜25-50 μm.) The results are given in Table 5 below.

TABLE 5
Liquid Composition Results

| Solvent blend (volume %) | | | | | |
|---|---|---|---|---|---|
| 4MA | MES. | NMP | CHB | DCRA | Doctor blade coating |
| 99 | 0 | 1 | 0 | Retracted | Not acceptable - could not |
| | | | | | form coating |
| 50 | 50 | 0 | 0 | Retracted | Not acceptable - coating |
| | | | | | formed, but edges retracted |
| 49.5 | 49.5 | 3.0 | 0.0 | Pinned | Acceptable coating, no |
| | | | | | retraction at edges |
| 48.0 | 48.0 | 3.0 | 1.0 | Pinned | Acceptable coating, no |
| | | | | | retraction at edges |

4MA = 4-methyl anisole
MES. = Mesitylene = 1,3,5 trimethylbenzene
NMP = N-methyl pyrrolidone
CHB = cyclohexylbenzene
DCRA = DCRA results

It can be seen from the Table 5, that the liquid compositions that pinned in the dynamic receding contact angle test were successfully deposited by the doctor blade coating. The predictions from the dynamic receding contact angle test were confirmed.

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. Further, references to values stated in ranges include each and every value within that range.

1. A liquid composition for liquid deposition onto an underlying layer, wherein the liquid composition comprises at least one organic electroactive material in a liquid medium, wherein the liquid medium comprises (a) at least 20% by volume, based on the total volume of the liquid medium, of a first solvent, the first solvent having a first surface tension and a first vapor pressure, and (b) at least 1% by volume, based on the total volume of the liquid medium, of a liquid organic additive, and wherein the liquid medium pins on the underlying layer as determined by a dynamic receding contact angle test and the first solvent in neat form retracts on the underlying layer as determined by the dynamic receding contact angle test.

2. A liquid composition for liquid deposition onto an underlying layer, wherein the liquid composition comprises at least one organic electroactive material in a liquid medium, wherein the liquid medium comprises (a) at least 20% by volume, based on the total volume of the liquid medium, of a first solvent which dissolves or disperses the organic electroactive material, the first solvent having a first surface tension and a first vapor pressure, and (b) at least 1% by volume, based on the total volume of the liquid medium, of a liquid organic additive, wherein the additive in neat form is capable of damaging the underlying layer.

3. The composition of claim 1, wherein the liquid organic additive is present at a level of 1-20% by volume, based on the total volume of the liquid medium.

4. The composition of claim 1, further comprising (c) 5-70% by volume, based on the total volume of the liquid medium, of a second solvent having a second surface tension, wherein the second surface tension is lower than the first surface tension.

5. The composition of claim 1, further comprising (d) 0.5-10% by volume, based on the total volume of the liquid medium, of a third solvent which has a third vapor pressure, wherein the third vapor pressure is lower than the first vapor pressure.

6. The composition of claim 1, wherein the underlying layer comprises a conductive polymer doped with a fluorinated acid polymer.

7. The composition of claim 6, wherein the electroactive material is a hole transport material.

8. The composition of claim 7, wherein the hole transport material is a small molecule, oligomer or polymer with triarylamine functionality.

9. The composition of claim 8, wherein the first solvent is an aromatic ether.

10. The composition of claim 8, wherein the additive is dimethylacetamide, N-methylpyrrolidone, pyridine, or propylene carbonate.

11. The composition of claim 8, further comprising a second solvent, wherein the second solvent is mesitylene, decane, 1-butanol, and propylene glycol propyl ether.

12. The composition of claim 8, further comprising a third solvent, wherein the third solvent is cyclohexylbenzene or dibenzylether.

13. The composition of claim 1, wherein the electroactive material comprises an electrically conductive polymer and a fluorinated acid polymer.

14. The composition of claim 13, wherein the electrically conductive polymer is doped with the fluorinated acid polymer.

15. The composition of claim 13, wherein the first solvent is water.

16. The composition of claim 13, wherein the underlying layer comprises hole transport material.
